(19) United States
(12) Patent Application Publication
(10) Pub. No.: US 2008/0100329 A1
(43) Pub. Date: May 1, 2008

(54) System and method for multi-up inline testing of radio frequency identification (RFID) inlays

(75) Inventors: Daniel Nguyen, Centereach, NY (US); Francisco Naranjo, Brentwood, NY (US); Gary Seims, East Setauket, NY (US); Peter Lam, Lake Grove, NY (US); David Reed, Holbrook, NY (US); Anthony LaSala, East Northport, NY (US)

Correspondence Address: STERNE, KESSLER, GOLDSTEIN & FOX P.L.L.C., 1100 NEW YORK AVENUE, N.W., WASHINGTON, DC, 20005, US

(73) Assignee: Symbol Technologies, Inc., Holtsville, NY (US)

(21) Appl. No.: 11/589,923

(22) Filed: Oct. 31, 2006

(51) Int. Cl. G01R 31/26; H04Q 5/22; G08B 13/14

(52) U.S. Cl. 324/765; 340/572.1; 340/10.1

(57) ABSTRACT

Methods, systems, and apparatuses for ways of testing tags are provided. In an aspect of the present invention, an antenna is mounted in a cavity of a surface. The antenna transmits a test signal, such as a radio frequency (RF) test signal, to the antenna of an adjacent tag, to test the adjacent tag. In aspects, multiple cavities having antennas may be arranged in various ways in the surface, such as in a “checkerboard pattern” (e.g., diagonally positioned from each other), to test multiple tags in a web of tags simultaneously. In another aspect, tags that are not being tested may be held at an electrical voltage, such as a ground voltage, to disable the tags from responding to the test signals of other tags. For example, in an aspect, a vacuum system may be used to hold tags in a web of tags to the surface to hold antennas of the tags at the electrical voltage.

### BACKGROUND OF THE INVENTION

1. Field of the Invention

The present invention relates to the testing of radio frequency identification (RFID) tag devices.

2. Background Art

Radio frequency identification (RFID) tags are electronic devices that may be affixed to items whose presence is to be detected and/or monitored. The presence of an RFID tag, and therefore the presence of the item to which the tag is affixed, may be checked and monitored by devices known as “readers.” Readers typically transmit radio frequency signals to which the tags respond. Each tag can store a unique identification number. The tags respond to the reader-transmitted signals by providing their identification number, bit-by-bit, so that they can be identified.

Ideally, tags are tested for proper performance prior to being sold. Demand for RFID tags is estimated to be for over a billion tags a year. Having an accurate high-speed test system that can support such volume is extremely critical. However, test systems that can rapidly and reliably handle large volumes of tags are not readily available. Current testing systems, which radiate test signals through the air, are extremely difficult to control and are reaching their limits in terms of the volume of tags that can be reliably tested.

Such systems can suffer from a variety of problems. For example, systems using radiated test signals sometimes unintentionally read adjacent tags, and thus have difficulty identifying a specific “bad” tag from a group of tags. Such systems may suffer from interference with the surrounding environment (e.g., interference with other radio frequency signals). When multiple testing antennas are used to test multiple tags, such systems may suffer from cross-talk with the adjacent systems.

Thus, what is needed is a RFID tag testing scheme which can handle very large volumes of tags, and can test the tags rapidly, in a reliable and repeatable fashion.

### BRIEF SUMMARY OF THE INVENTION

Methods, systems, and apparatuses for testing tags are described. In an aspect of the present invention, an antenna is mounted in a cavity formed in a surface. The antenna transmits a test signal, such as a radio frequency (RF) test signal, to the antenna of a tag adjacent to the cavity, to test the adjacent tag.

In aspects, multiple cavities having antennas may be arranged in various ways in the surface, such as in a “checkerboard pattern” (e.g., diagonally positioned from each other), to test multiple tags in a web of tags simultaneously.

In another aspect, tags in the web that are not currently being tested may be held at an electrical voltage, such as a ground voltage, to disable the tags from responding to the test signals of other tags. For example, in an aspect, a vacuum system may be used to hold other tags in the web to the surface to hold antennas of the other tags at the electrical voltage.

In an example aspect of the present invention, a system for testing radio frequency identification (RFID) tags, includes a body having a surface, wherein the surface has a first cavity and a second cavity formed therein, a first antenna mounted in the first cavity, and a second antenna mounted in the second cavity. The surface is configured to receive a web of RFID tags such that a first tag of the web of RFID tags is positioned adjacent to the first cavity, a second tag of the web of RFID tags is positioned adjacent to the second cavity, and at least one other tag of the web of RFID tags is in contact with the surface to couple an antenna of the at least one other tag to an electrical voltage. The first antenna is configured to transmit a first RFID communication signal to the first tag and to receive a first response signal from the first tag. The second antenna is configured to transmit a second RFID communication signal to the second tag and to receive a second response signal from the second tag.

In another aspect of the present invention, a method for testing radio frequency identification (RFID) tags is provided. A web of RFID tags is received on a surface such that a first tag of the web of RFID tags is positioned adjacent to a first cavity in the surface and a second tag of the web of RFID tags is positioned adjacent to a second cavity in the surface. A first RFID communication signal is transmitted from a first antenna mounted in the first cavity. The first RFID communication signal is configured to test the first tag. A second RFID communication signal is transmitted from a second antenna mounted in the second cavity. The second RFID communication signal is configured to test the second tag.

Subsequently to testing the first and second tags, the web may be advanced so that third and fourth tags are positioned adjacent to the first and second cavities for test. This may be repeated as often as needed so that numerous tags in a web may be tested. Furthermore, as described above, any number of tags in a web may be simultaneously tested through the use of multiple cavities in a surface, each cavity including one or more test antennas.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a plan view of an example radio frequency identification (RFID) tag.

FIG. 2 shows a plan view of an example web of tags that is a continuous roll type.

FIGS. 3 and 4 show views of an example tag test system, according to an embodiment of the present invention.

FIGS. 5 and 6 show a web of tags under test using the tag test system of FIGS. 3 and 4, according to an example embodiment of the present invention.

FIG. 7 shows an example tag assembly station, according to an embodiment of the present invention.

FIG. 8 shows a vacuum system used to hold tags of a web to a surface, according to an example embodiment of the present invention.

FIG. 9 shows a view of an example tag test system, according to an embodiment of the present invention.

FIGS. 10 and 11 show a web of tags under test using the tag test system of FIG. 9, according to an example embodiment of the present invention.

FIG. 12 shows a view of an example tag test system, according to an embodiment of the present invention.

FIG. 13 shows a web of tags under test using the tag test system of FIG. 12, according to an example embodiment of the present invention.

FIGS. 14 and 15 show example cavities in surfaces, according to embodiments of the present invention.

FIG. 16 shows a view of an example tag test system, according to an embodiment of the present invention.

FIG. 17 shows a flowchart for testing tags, according to an example embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Example Embodiments

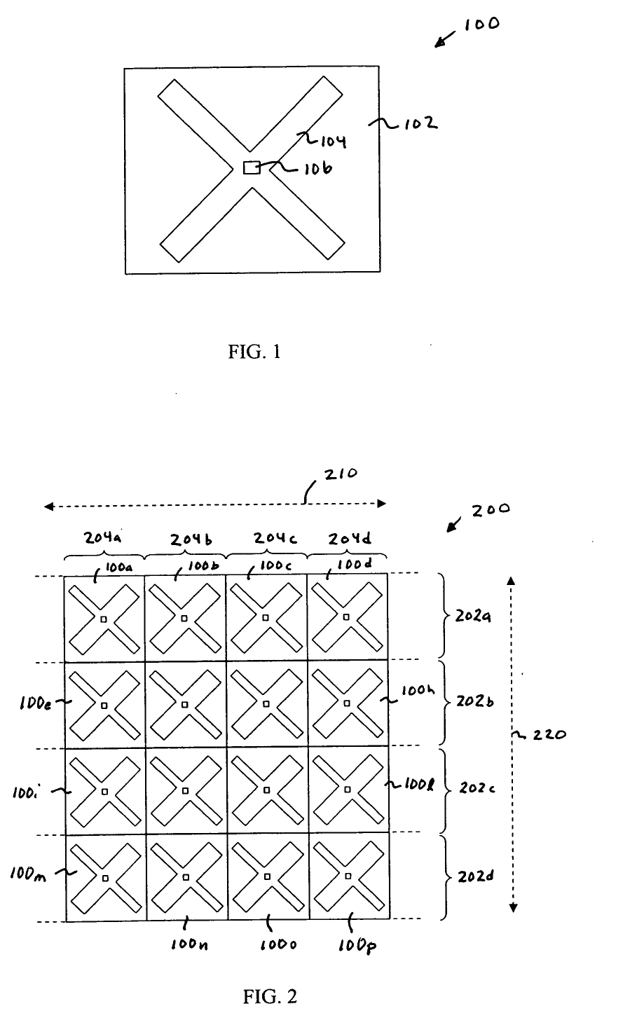

The present invention is applicable to any type of RFID tag. FIG. 1 shows a plan view of an example radio frequency identification (RFID) tag 100. Tag 100 includes a substrate 102, an antenna 104, and an integrated circuit (IC) 106. Antenna 104 is formed on a surface of substrate 102. Antenna 104 may include any number of one or more separate antennas. IC 106 includes one or more integrated circuit chips/dies, and can include other electronic circuitry. IC 106 is attached to substrate 102, and is coupled to antenna 104. IC 106 may be attached to substrate 102 in a recessed and/or non-recessed location. IC 106 controls operation of tag 100, and transmits signals to, and receives signals from RFID readers using antenna 104. Tag 100 may additionally include further elements, including an impedance matching network and/or other circuitry. The present invention is applicable to tag 100, and to other types of tags, including surface acoustic wave (SAW) type tags.

Embodiments described herein are also applicable to all forms of tags, including tag “inlays” and “labels.” A “tag inlay” or “inlay” is defined as an assembled RFID device that generally includes an integrated circuit chip (and/or other electronic circuit) and antenna formed on a substrate, and is configured to respond to interrogations. A “tag label” or “label” is generally defined as an inlay that has been attached to a pressure sensitive adhesive (PSA) construction, or has been laminated, and cut and stacked for application. One form of a “tag” is a tag inlay that has been attached to another surface, or between surfaces, such as paper, cardboard, etc., for attachment to an object to be tracked, such as an article of clothing, etc.

Volume production of RFID tags, such as tag 100, is typically accomplished on a printing web based system. For example, in such a system, the tags are assembled in a web of substrates, which may be a sheet of substrates, a continuous roll of substrates, or other group of substrates. For instance, FIG. 2 shows a plan view of an example web 200 that is a continuous roll type. As shown in FIG. 2, web 200 may extend further in the directions indicated by arrow 210. Web 200 includes a plurality of tags 100a-p. In the example of FIG. 2, the plurality of tags 100a-p in web 200 is arranged in a plurality of rows 202 and columns 204. The present invention is applicable to any number of rows 202 and columns 204 of tags, and to other arrangements of tags. For instance, in the example of FIG. 2, web 200 includes four rows 202a-202d that extend along a length of web 200 (indicated by arrow 210) in parallel, and includes four columns 204a-204d that extend across a width of web 200 (indicated by arrow 220) in parallel.

On a web, such as web 200, RFID tags are typically assembled/positioned as close to each other as possible to maximize throughput, thus making the process of reading and testing individual tags difficult. Because of the close spacing, it is very difficult to localize a radiated (e.g., radio frequency) reader field to excite only one tag.

According to embodiments of the present invention, tags are tested in a more reliable and repeatable fashion than in conventional tag testing schemes. In embodiments of the present invention, an antenna mounted in a cavity of a surface transmits a test signal, such as a radio frequency (RF) test signal, to the antenna of an adjacent tag. Antennas/cavities may be arranged in various ways, such as in a “checkerboard pattern” (e.g., diagonally positioned from each other), to test multiple tags simultaneously. Tags that are not being tested may be held at an electrical voltage, such as a ground voltage, to disable the tags from responding to the test signals of other tags.

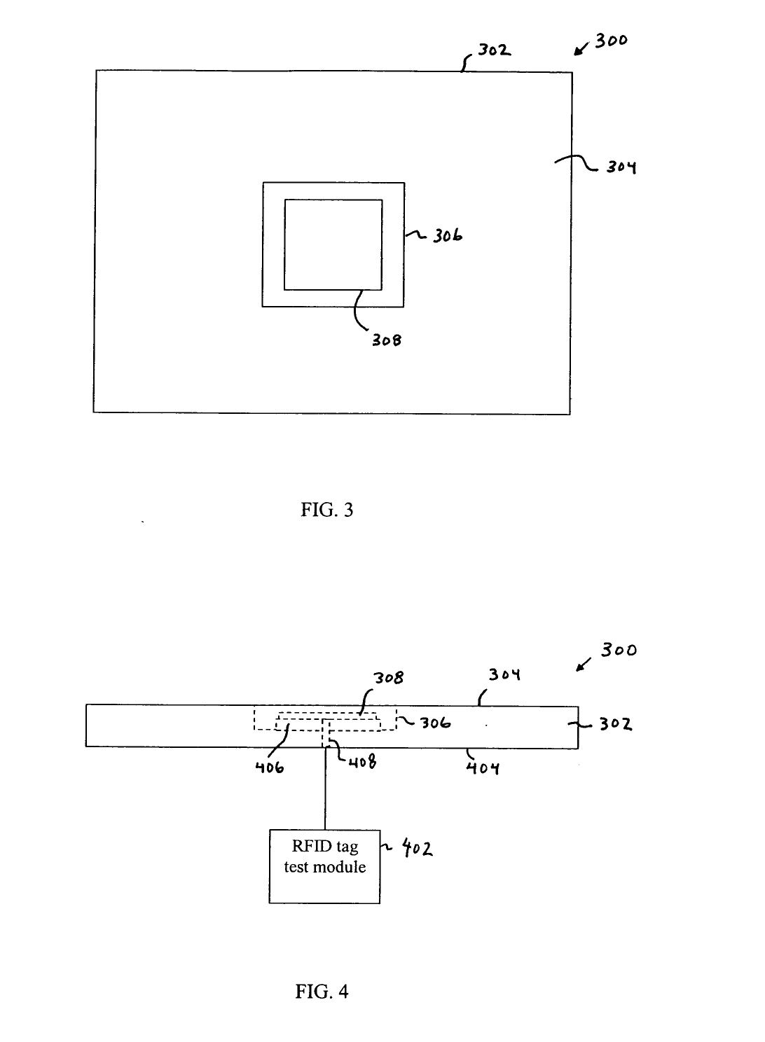

For example, FIG. 3 shows a surface 304 of a body 302 having a cavity 306, in a tag test system 300, according to an example embodiment of the present invention. Surface 304 is configured to receive a web of tags, such as web 200 shown in FIG. 2, for test. FIG. 4 shows a side view of body 302 in tag test system 300 of FIG. 3. As shown in FIGS. 3 and 4, an antenna 308 is mounted in cavity 306. Furthermore, as shown in FIG. 4, a RFID tag test module 402 is coupled to antenna 308.

Body 302 may be any type of suitable structure capable of receiving a web of tags, and of having cavity 306 mounting antenna 308 therein. For instance, body 302 is shown in FIG. 4 as being planar or plate-shaped, having opposing surfaces (first surface 304 and a second surface 404). However, body 302 can have other shapes. Body 302 may be made of any suitable material, including a metal (e.g., copper, aluminum, steel, etc.) or combination of metals/alloy, a plastic material, glass, a ceramic, etc. In an embodiment, body 302 is made of an electrically conductive material, such as a metal. In another embodiment, surface 304 of body 302 is plated with an electrically conductive material.

Cavity 306 is shown in FIG. 3 as being rectangular shaped. For example, cavity 306 may be rectangular shaped to conform to an adjacently positioned rectangular shaped tag and/or a tag having an antenna (or antennas) with a rectangular outer profile.

However, in alternative embodiments, cavity 306 can have other shapes. Furthermore, cavity 306 can have any suitable depth, as desired for a particular application. Note that in an embodiment, cavity 306 may be filled with an encapsulating material to environmentally protect antenna 308, to better hold antenna 308 in place in cavity 306, to provide a level surface for cavity 306 that is flush with surface 304, and/or for other reasons.

In the example of FIG. 3, antenna 308 is shown as rectangular shaped. For example, in an embodiment, antenna 308 may be a patch antenna. However, alternative embodiments, antenna 308 may have other shapes and/or may be an another type of antenna, including a dipole, dual dipole, loop, etc. For description of example patch antennas, refer to U.S. application Ser. No. 11/265,143, filed Nov. 3, 2005, titled “Low Return Loss Rugged RFID Antenna,” now pending, which is incorporated by reference herein in its entirety. When body 302 is made of an electrically conductive material, antenna 308 is electrically isolated from body 302. For example, as shown in FIG. 4, antenna 308 is positioned on an electrically non-conductive material 406 that mounts antenna 308 on body 302 in cavity 306. An electrical link 408 couples antenna 308 and RFID tag test module 402. RFID tag test module 402 transmits a RFID communication signal to antenna 308 over electrical link 408. Antenna 308 transmits the RFID communication signal to a tag under test. RFID tag test module 402 receives a tag response signal over electrical link 408 that was received by antenna 308. Electrical link 408 may include any type of electrical conductor for transmitting RF signals, such as a coaxial cable. Electrical link 408 may be routed through one or more ports in second surface 404 of body 302.

RFID tag test module 402 provides test signals, such as RF test signals, to antenna 308 for testing tags. RFID tag test module 402 includes software, hardware, and/or firmware, or any combination thereof, for testing functionality of tags. This incorporated software/hardware/firmware may be referred to as a “test controller” included in RFID tag test module 402. RFID tag test module 402 may be incorporated into a computer system. RFID tag test module 402 can further include one or more storage devices for storing information regarding the test system and tags under test, including memory components, disc-based storage, magnetic storage devices, optical storage, etc. Furthermore, RFID tag test module 402 can include a user interface, such as including a keyboard, display, graphical user interface (GUL), pointing device, and/or other visual and/or audio indicators, for interacting with RFID tag test module 402 as needed.

RFID tag test module 402 generates one or more test signals to test tags. For example, RFID tag test module 402 may communicate with a tag under test according to any RFID communication protocol. RFID tag test module 402 may generate the test signal(s) according to one or more interrogation/read protocols, as would be known to persons skilled in the relevant art(s), to read/communicate with tags under test. Example such protocols include binary protocols, tree traversal protocols, slotted aloha protocols, and those required by the following standards: EPC Class 0; EPC Class 1; and EPC Gen 2. Any future developed communication algorithms/protocols are also within the scope and spirit of the present invention.

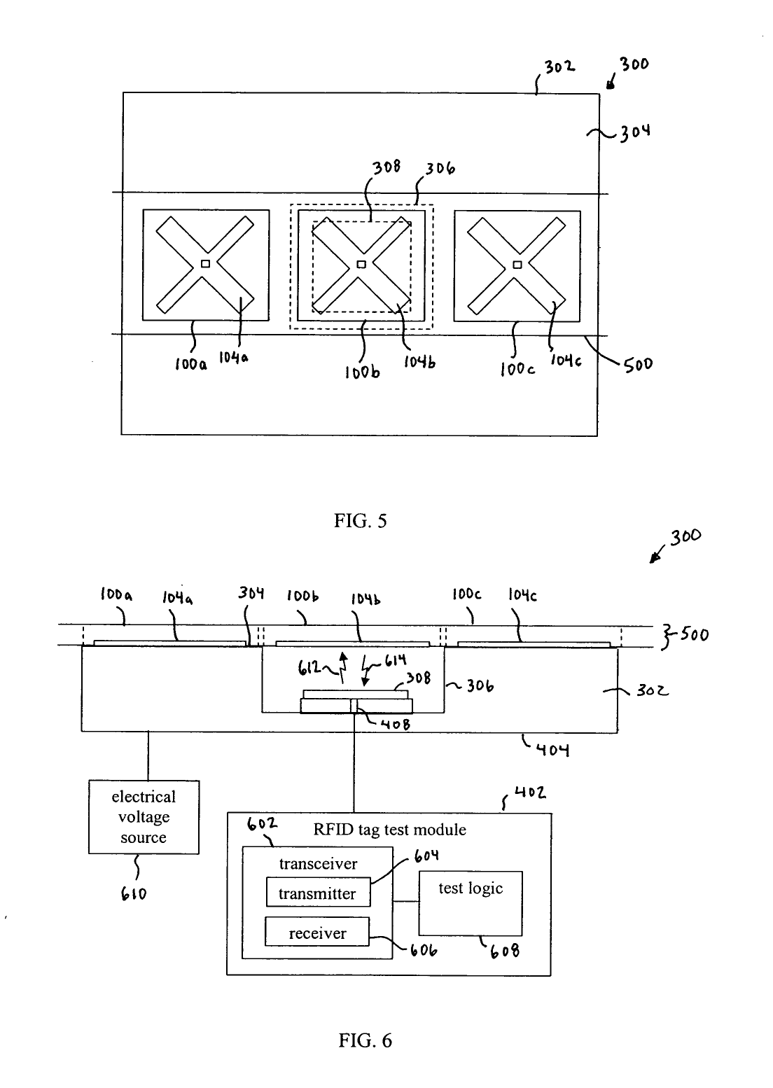

FIG. 5 shows a plan view of surface 304 of body 302 receiving a web 500 in tag test system 300. The portion of web 500 shown in FIG. 5 includes tags 100a-100c. Tag 100b is positioned adjacent to (e.g., is positioned over; at least partially covers) cavity 306. FIG. 6 shows a cross-sectional view of tag test system 300 of FIG. 5. Tag 100b is tested by RFID tag test module 402. As shown in the embodiment of FIG. 6, tag test module 402 includes a transceiver 602 coupled to a test logic 608. Test logic 608 operates a test protocol, causing transceiver 602 to transmit test signals with test information. Test logic 608 also processes test response data received from tags. Transceiver 602 is configured to generate signals to transmit to a tag under test, and to down-convert and/or demodulate signals received from tags. As shown in FIG. 6, transceiver 602 includes a transmitter 604 and a receiver 606. In the example of FIG. 6, transmitter 604 generates a RFID test signal. The RFID test signal is coupled to antenna 308 by electrical link 408. Antenna 308 receives the RFID test signal and transmits a RFID communication signal 612 to test tag 100b. When able to respond, tag 100b transmits a response signal 614. Antenna 308 receives response signal 614. Antenna 308 couples response signal 614 to transceiver 602 by electrical link 408. Test logic 608 processes the response information received from tag 100b in response signal 614 to determine whether tag 100b passed the test.

For instance, the test signal(s) of RFID tag test module 402 may have interrogated tag 100b for its identification number. Test logic 608 evaluates whether tag 100b properly responded with its identification number. In further embodiments, data other than the identification number can be read from tag 100b, to test other data, storage elements, and/or features of tag 100b. In embodiments, any type of test may be performed, to test any feature, parameter, characteristic, etc., of tag 100b.

If the identification number is properly received from tag 100b (and/or the tag otherwise responds properly), RFID tag test module 402 determines that tag 100b has passed the test, and RFID tag test module 402 proceeds accordingly. For example, in an embodiment, RFID tag test module 402 provides an indication that tag 100b passed the test by illuminating an indicator light, by displaying test result information on a graphical display, by storing test result information in storage, and/or by taking other action (or no action). If the identification number is improperly received (and/or the tag otherwise responds improperly), RFID tag test module 402 determines that tag 100b did not pass the test, and may not be functioning properly. For example, an improperly functioning tag may generate a response that is incorrect (i.e., is not the response expected from the tag for the particular test being performed, including a non-response). In such a situation, RFID tag test module 402 may provide an indication that tag 100b failed the test by marking tag 100b as defective, by illuminating an indicator light, by displaying test result information on a graphical display, by storing the test result information in storage, and/or by taking other action. In this manner, the failed tag 100b can subsequently be repaired, disposed, or recycled.

As shown in FIG. 6, tags 100a and 100c are in contact with surface 304 of body 302. As described above, in an embodiment, body 302 may be electrically conductive. In FIG. 5, an electrical voltage source 610 is coupled to body 302 to hold body 302 at a voltage, such as a ground voltage or other voltage level. Antennas 104a and 104c of tags 100a and 100c, respectively are held at the voltage supplied by electrical voltage source 610, because they are in contact with surface 304. Because of this, tags 100a and 100c are disabled from receiving RFID communications signals, and therefore will not erroneously respond to test signals transmitted to tag 100b by antenna 308. Thus, tag 100b can be tested in isolation. Any number of tags of web 500 can be disabled in this manner by sizing an area of surface 304 as desired, to prevent other tags from responding to test signals directed to a tag under test.

In embodiments, RFID tag test module 402 described herein can include elements of conventional RFID readers. For example, depending on the particular application, RFID tag test module 402 may incorporate the power controls and read and write capabilities of an RFID reader, to control power output to antenna 308, and to conduct the testing of tags. For instance, example conventional readers having features that are applicable to the embodiments of the present invention include AR400 and XR400 readers sold by Symbol Technologies of Holtsville, N.Y. The AR400 and XR400 are example 4-port readers that may be used in a “multi-channel” testing configuration, such as described in further detail below.

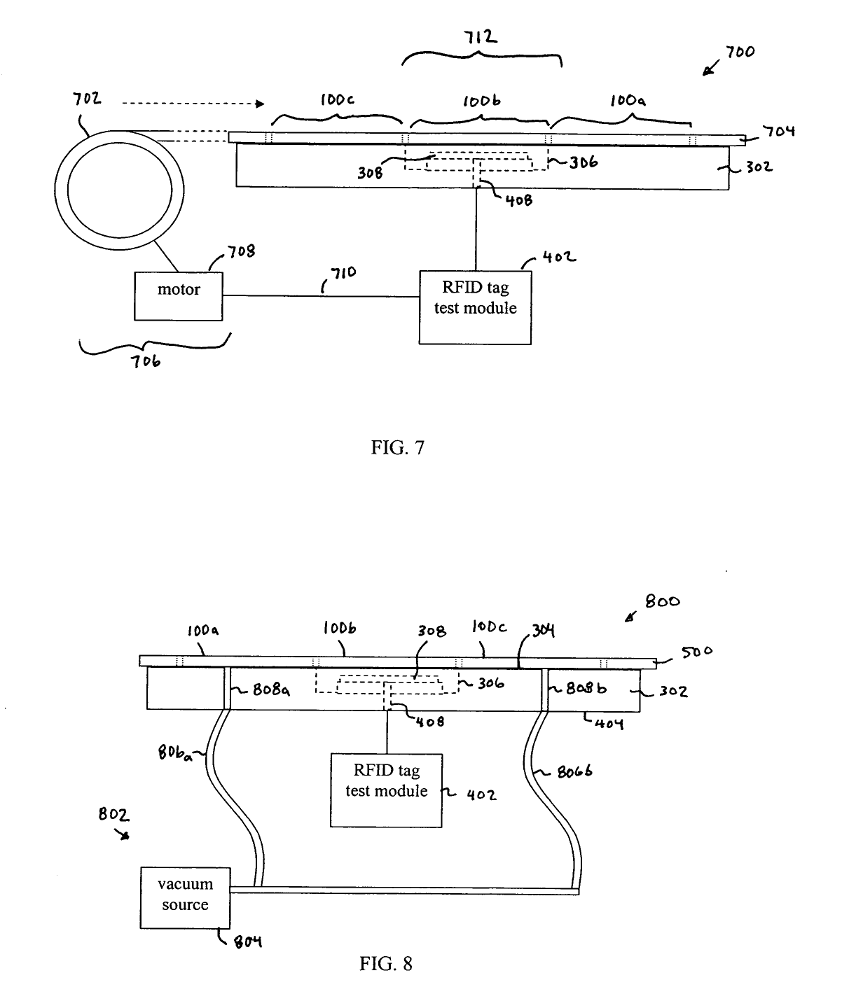

In embodiments, the systems described herein may be incorporated into a tag assembly line (TAL), which may be a partially or fully automated assembly line. For example, FIG. 7 shows a side view of a tag assembly line 700 incorporating tag test functionality, according to an embodiment of the present invention. In the example of FIG. 7, tag assembly line 700 receives a continuous roll 702 of substrates, as web 704. Web 704 includes a plurality of substrates arranged in an array. Web 704 has a width in the X-direction (i.e., into the paper of FIG. 7) that is one or more substrates across. Web 704 has a length in the Y-direction that is substantially continuous (e.g., the length of a roll), and typically many substrates long. At one or more locations of tag assembly line 700 (not shown in FIG. 7) prior to a tag testing station, IC 106 (shown in FIG. 1) and/or other components, are applied to the substrates of web 704, and further tag assembly may occur, to produce tags 100 in web 704.

Once tags 100 have been assembled in web 704 at least to the extent that they are functional, they can be tested at a testing station 712. Within testing station 712, FIG. 7 shows tag 100b of web 704 positioned proximate cavity 608. After testing of tag 100b, web 704 can be advanced, and a next tag of web 704 (e.g., tag 100c) can be tested in a similar fashion. This process can continue until all the tags of web 704 have been tested. FIG. 7 shows a web advancing mechanism 706, according to an example embodiment of the present invention. Web advancing mechanism 706 may be any type of web advancing mechanism, including a roll-to-roll conveyor system, a sheet web advancing mechanism, etc. For example, in FIG. 7, web advancing mechanism 706 includes roll 702 and a motor 708. Motor 708 is coupled to roll 702. Motor 708 receives a control signal 710 from RFID tag test module 402 that directs motor 708 to move (e.g., rotate) roll 702, to advance web 704. For example, motor 708 may be a stepper motor, or other motor type.

FIG. 8 shows a tag test system 800 similar to tag test system 300 of FIG. 3, with the addition of a vacuum system 802, according to an example embodiment of the present invention. As described above, tags of a web other than a tag under test may be held in contact with surface 304 of body 302 to hold the other tags at a voltage to disable them. Vacuum system 802 may be used to hold these other tags onto surface 304 to hold them at the voltage, and also so that the tag under test is held in proper position (e.g., so that the antenna of the tag under test is over cavity 306 and does not contact surface 304), and/or for other reasons.

As shown in the embodiment of FIG. 8, vacuum system 802 includes a vacuum source 804 and tubes/hoses 806. Furthermore, as shown in FIG. 8, body 302 has a plurality of openings 808 that are open at first surface 304 and second surface 404. In the example of FIG. 8, a first hose 806a is coupled between vacuum source 804 and first opening 808a, and a second hose 806b is coupled between vacuum source 804 and second opening 808b. Vacuum source 804 is configured to apply a suction to web 500 through hoses 806 and openings 808 to hold web 500 in contact with surface 304. Any number and combination of openings 808, hoses 806, and vacuum sources 804 may be used in embodiments.

Note that embodiments of the present invention are applicable to the testing of tags having any number of antennas, including one antenna, two antennas (e.g., a dual dipole antenna), three antennas, and further antennas.

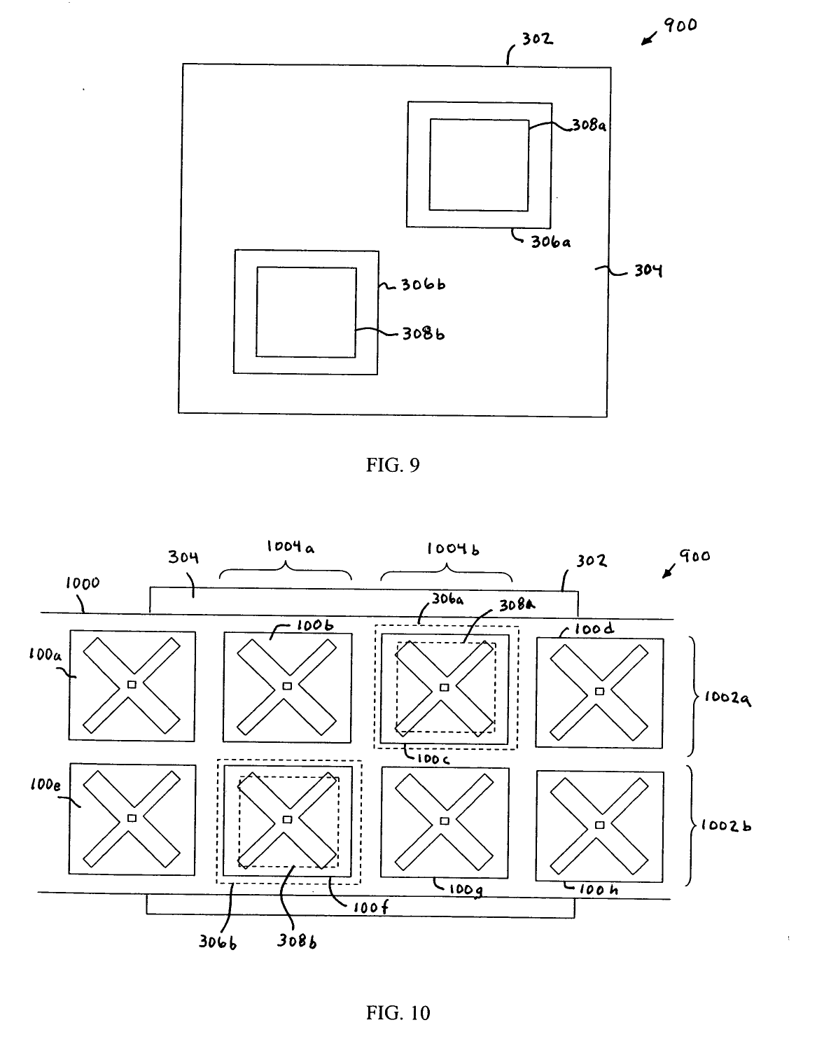

Furthermore, in embodiments, multiple tags may be tested in parallel, according to embodiments of the present invention. For example, FIG. 9 shows a multi-tag test system 900, according to an embodiment of the present invention. As shown in FIG. 9, test system 900 is similar to test system 300 shown in FIG. 3, except that in FIG. 9, body 302 includes two cavities 306—first cavity 306a and second cavity 306b—which each include an antenna 308—first antenna 308a and second antenna 308b, respectively. FIG. 10 shows a plan view of surface 304 of body 302 receiving a web 1000 in tag test system 900. The portion of web 1000 shown in FIG. 10 includes tags 100a-100h. Tag 100c is positioned adjacent to (e.g., is positioned over; at least partially covers) cavity 306a and tag 100f is positioned adjacent to cavity 306b. Tags 100c and 100f are directly diagonally positioned in web 1000 relative to each other. Tag 100c is located in a first row 1002a and a second column 1004b of web 1000, and tag 100f is located in a second row 1002b and a first column 1004a of web 1000. Thus, first and second cavities 306a and 306b are positioned directly diagonally to each other in surface 302. As will become further apparent below, this positioning of first and second cavities 306a and 306b (and of tags 100c and 100f) can also be referred to as being “staggered” or as being arranged according to a “checkered” or “checkerboard pattern.” These patterns include arrangements where cavities are not directly adjacent to each other in rows or columns, but may be diagonally positioned relative to each other.

Note that in an alternative embodiment, first and second cavities 306a and 306b may be positioned in surface 304 to test tags 100 that are positioned adjacently in the same row or column of web 1000. For example, in such an alternative embodiment, cavities 306a and 306b may be positioned in surface 304 to test tags 100b and 100f simultaneously.

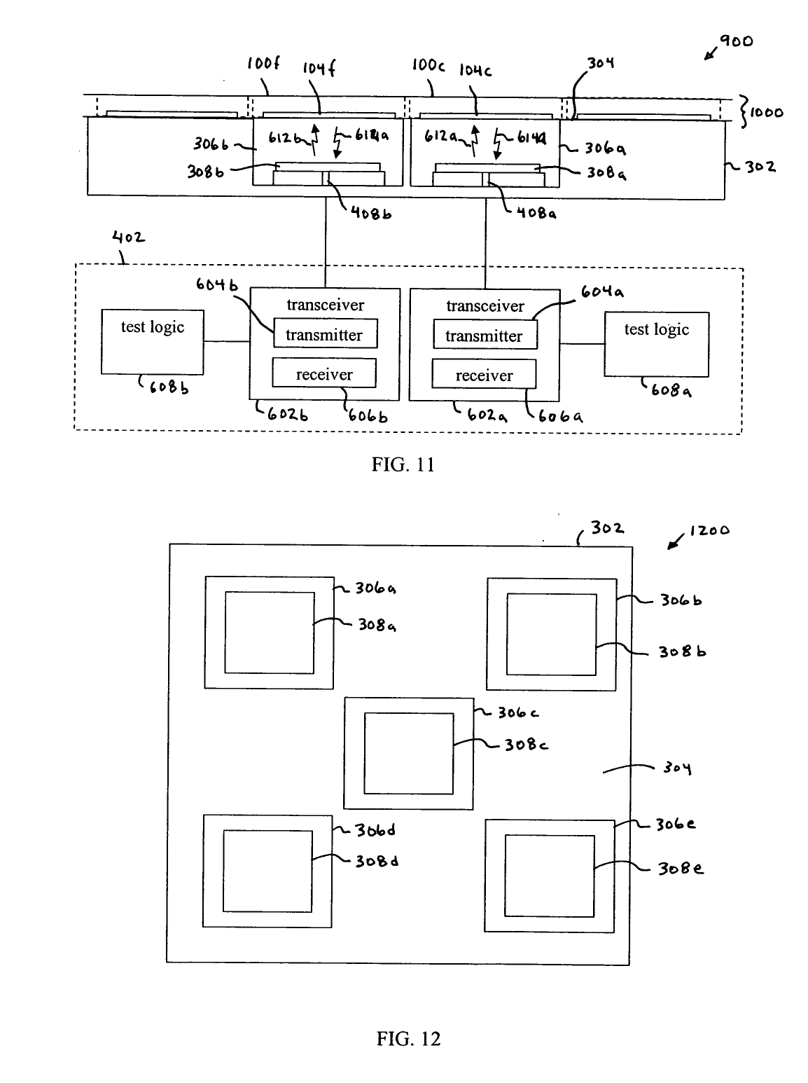

FIG. 11 shows a cross-sectional view of tag test system 900. In FIG. 11, for illustrative purposes, cavities 306a and 306b are both shown, even though they are positioned adjacent to different rows of web 1000. First antenna 308a in first cavity 306a and second antenna 308b in second cavity 306b are each configured to test a respective tag of a web in a similar fashion as antenna 308 in cavity 306 described above. Thus, their operation is not described in detail for reasons of brevity. In the embodiment of FIG. 11, RFID tag test module 402 includes a first transceiver 602a, a second transceiver 604b, a first test logic 608a, and a second test logic 608b. Tag 100c is tested by first transceiver 602a and first test logic 608a, and tag 100f is tested by second transceiver 602b and second test logic 608b, in a similar manner as described above with regard to FIG. 6 for tag 102b.

Note that because of the physical separation and electrical isolation of cavities 306a and 306b in body 302, antennas 308a and 308b may transmit their test signals (first and second RFID communication signals 612a and 612b, respectively) simultaneously (or at different times). The walls of cavities 306a and 306b prevent test signals transmitted from an antenna in one cavity from being received by the antenna in the other cavity. Electrical isolation is improved when body 302 is held at an electrical voltage, such as ground, as described above. Furthermore, in an embodiment where tags 100a, 100b, 100d, 100e, 100g, and 100h are in contact with surface 304, when surface 304 is held at an electrical level (e.g., ground), tags 100a, 100b, 100d, 100e, 100g, and 100h are prevented from responding to the test signals. Tags 100c and 100f (when able) transmit first and second response signals 614a and 614b, respectively, which are respectively received by antennas 308a and 308b.

As described above, tags of a web can be further arranged and tested in a staggered or checkerboard pattern, where multiple tags in the web are tested by antennas 308 in separate cavities 306. Such a staggered/checkerboard pattern can be extended in any manner. For example, FIG. 12 shows a tag test system 1200 where cavities 306a-306e are formed in surface 304 of body 302 in a checkerboard pattern, according to another embodiment of the present invention. Cavities 306a-306e include antennas 308a-308e, respectively. Each pair of cavities/antenna pair of FIG. 12 is configured to test a respective tag of a web in a similar fashion as described above. Thus, operation of each cavity/antenna pair is not described in detail for reasons of brevity. Furthermore, each cavity/antenna pair may test a tag simultaneously with the other cavity/antenna pairs.

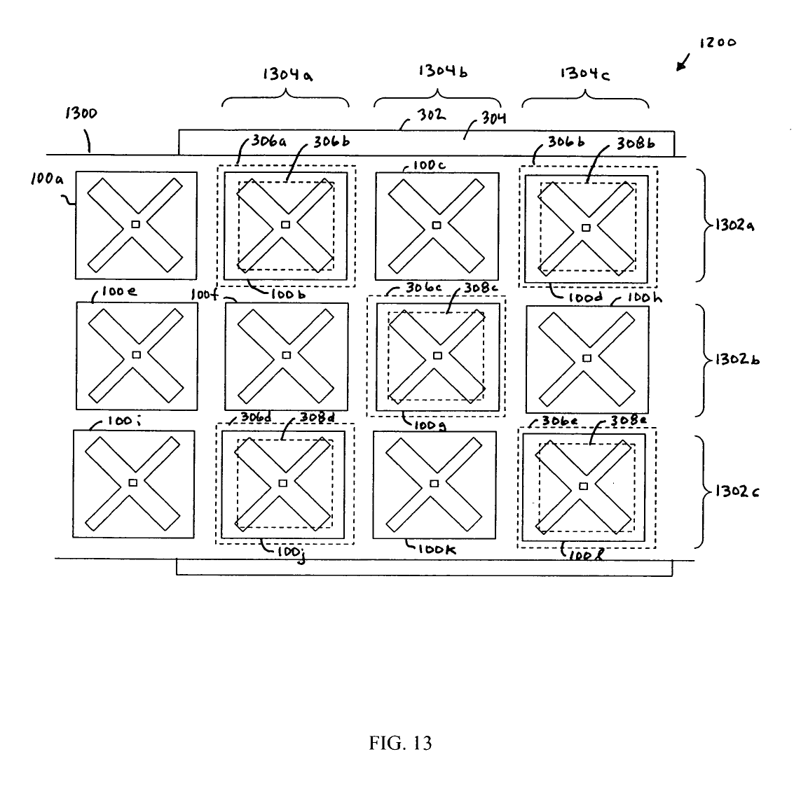

FIG. 13 shows a plan view of surface 304 of body 302 receiving a web 1300 in tag test system 1200. The portion of web 1300 shown in FIG. 13 includes tags 100a-100l. Tag 100b is positioned adjacent to (e.g., is positioned over; at least partially covers) cavity 306a, tag 100d is positioned adjacent to cavity 306b, tag 100g is positioned adjacent to cavity 306c, tag 100j is positioned adjacent to cavity 306d, and tag 100l is positioned adjacent to cavity 306e. Thus, tags 100b, 100d, 100g, 100j, and 100l are positioned to be tested by antennas 308a-308e, respectively, and are positioned in a checkerboard pattern in web 1300. Tags 100b, 100d, 100j, and 100l are each positioned directly diagonal to tag 100g in web 1300. Tag 100b is located in a first row 1302a and a first column 1304a of web 1300, tag 100d is located in first row 1302a and a third column 1304c of web 1300, tag 100g is located in a second row 1302b and a second column 1304b of web 1300, tag 100j is located in a third row 1302c and first column 1304a of web 1300, and tag 100l is located in third row 1302c and third column 1304c of web 1300.

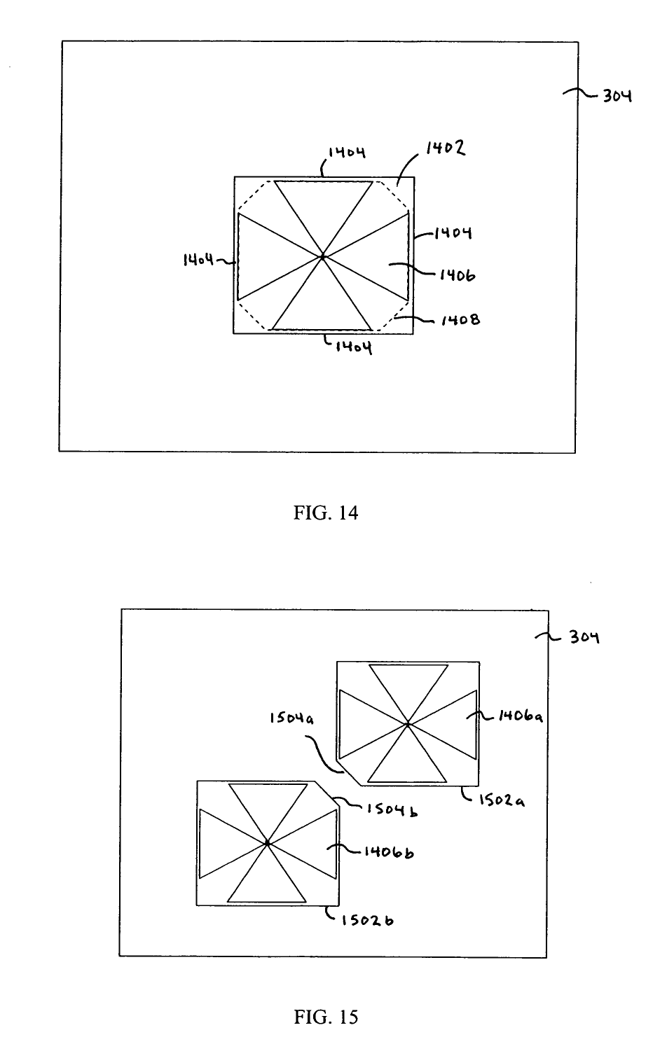

As described above, cavities 306 may have any suitable size and shape. For example, in an embodiment, a cavity 306 may be configured to accommodate an adjacently positioned tag antenna to be tested. For example, FIG. 14 shows a cavity 1402 in surface 304 having an outer profile defined by outer edges 1404 of cavity 1402. FIG. 14 also shows a tag antenna 1406 of a tag (not shown in FIG. 14) positioned adjacent to cavity 1402. Tag antenna 1406 has an outer profile 1408 defined generally by the outermost edges of tag antenna 1406. As shown in FIG. 14, cavity 1402 has an outer profile that is greater than or equal to (≧) outer profile 1408 of tag antenna 1406. In this manner, surface 304 does not contact tag antenna 1406, and thus cannot couple a voltage (when present) to tag antenna 1406. Furthermore, the entire area of tag antenna 1406 is available to receive a RFID communication signal from a test antenna in cavity 1402 (not shown in FIG. 14), and thus a test signal may be better received.

In another example embodiment, FIG. 15 shows first and second cavities 1502a and 1502b in surface 304 that are substantially rectangular, with modified corners 1504a and 1504b, respectively. Comers 1504a and 1504b are modified so that first and second cavities 1502a and 1502b can be positioned more closely together on surface 304 to accommodate antennas of tags under test that are close together in a web of tags received by surface 304. For example, tag antennas 1406a and 1406b are shown in FIG. 15 as positioned adjacent to cavities 1502a and 1502b, respectively (A web that includes tag antennas 1406a and 1406b is not shown in FIG. 15). Because corners 1504a and 1504b are modified, cavities 1502a and 1502b can be closer together than cavities having unmodified corners, such as cavities 306a and 306b shown in FIG. 9. For example, if cavities 306a and 306b of FIG. 9 were as closely positioned as cavities 1502a and 1502b, they would overlap and would not be isolated from each other. By having modified corners 1504a and 1504b, cavities 1502a and 1502b can remain isolated from each other for conducting tag tests.

In the example of FIG. 15, corners 1504a and 1504b are shown modified as being flattened or cut-off. However, in alternative embodiments, corners 1504a and 1504b may be modified in other ways, as would be apparent to persons skilled in the relevant art(s).

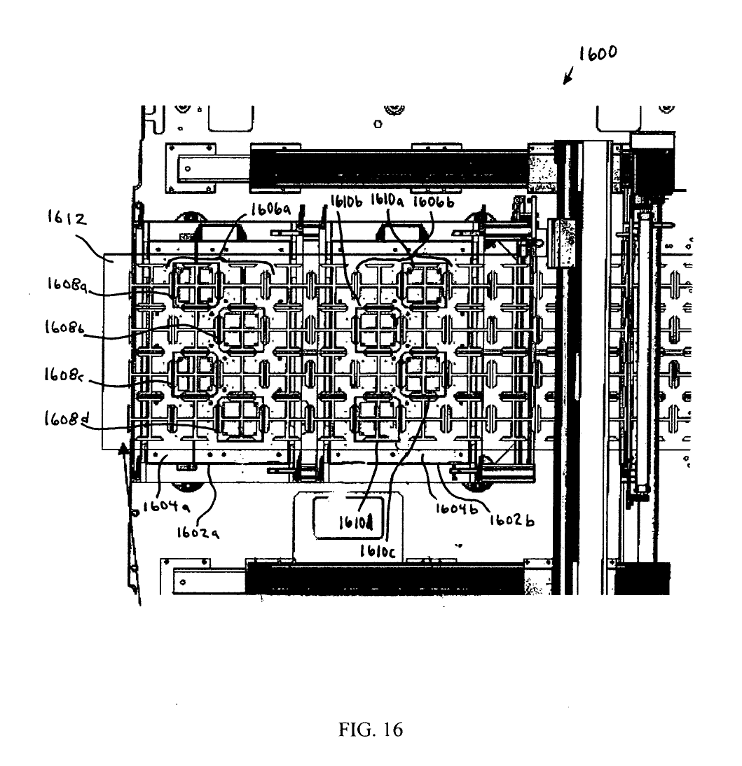

FIG. 16 shows a plan view of an example tag test system 1600, according to an embodiment of the present invention. Tag test system 1600 includes a first body 1602a having a surface 1604a, a second body 1602b having a surface 1604b, and a web 1612 of tags. Furthermore, outlines of cavities in surfaces 1604a and 1604b are shown, including a first group of cavities 1606a in surface 1604a and a second group of cavities 1606b in surface 1604b. As shown in FIG. 16, first group of cavities 1606a includes cavities 1608a-1608d arranged in two columns in a staggered/checkerboard pattern. Second group of cavities 1606b includes cavities 1610a-1610d arranged in another two columns in a staggered/checkerboard pattern. Also, as shown in FIG. 16, each of cavities 1608a-1608d and 1610a-1610d have modified corners, similarly to cavities 1502a and 1502b shown in FIG. 15. For example, cavities 1608a, 1608d, 1610a, and 1610d, which are located at ends of their respective columns of web 1612, each have a single modified corner. Cavities 1608b, 1608c, 1610b, and 1610c, which are each located in their respective columns between two cavities, each have a pair of modified corners.

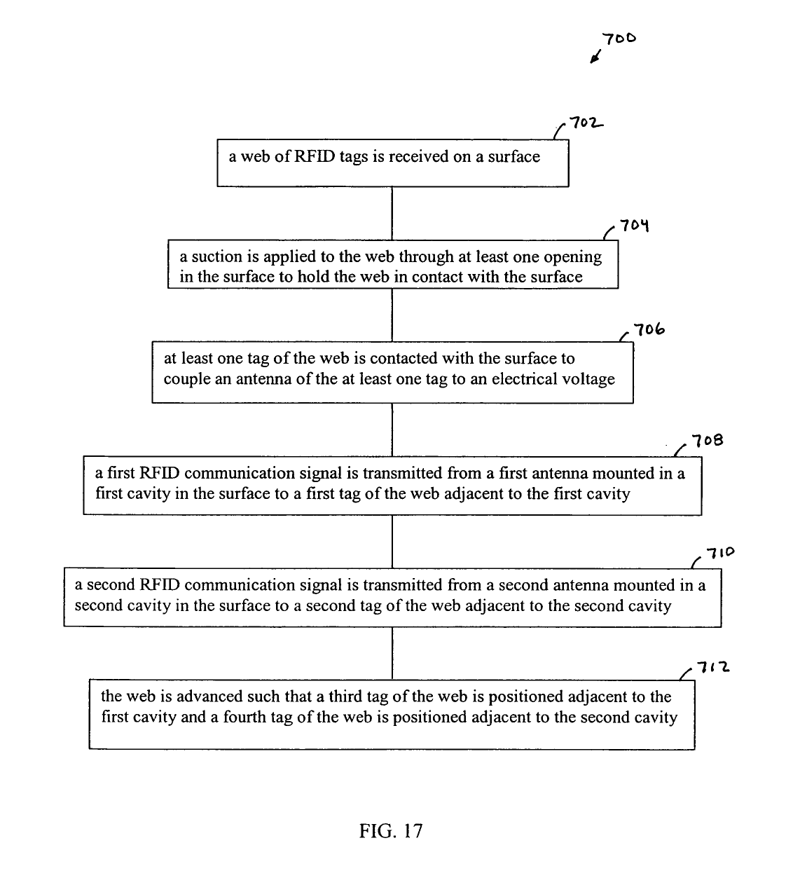

FIG. 17 shows a flowchart 1700 providing example steps for testing tags, according to an example embodiment of the present invention. For example, the structures described above with respect to FIGS. 3-16 may be used to test tags according to flowchart 1700. Other structural and operational embodiments will be apparent to persons skilled in the relevant art(s) based on the following discussion. For illustrative purposes, flowchart 1700 describes a process for testing two tags simultaneously. However, flowchart 1700 may be modified for testing greater numbers of tags simultaneously (or a single tag), as would be understood by persons skilled in the relevant art(s) from the teachings herein.

Flowchart 1700 begins with step 1702. In step 1702, a web of RFID tags is received on a surface. For example, as shown in FIGS. 5, 10, and 13, webs 500, 1000, 1300, and 1612 may be received by surfaces, such as surface 304 of body 302.

In step 1704, a suction is applied to the web through at least one opening in the surface to hold the web in contact with the surface. For example, as shown in FIG. 8, a vacuum source 804 may be used to apply a suction to a web, such as web 500, through openings 808 to hold the web in contact with the surface. Step 1704 may be performed in some embodiments.

In step 1706, at least one tag of the web is contacted with the surface to couple an antenna of the at least one tag to an electrical voltage. For example, as described above, tags in a web other than those under test may be coupled to an electrical voltage to disable them from responding to test signals. FIG. 6 shows an electrical voltage source 610 that applies an electrical voltage to body 302, which is thereby applied to antennas of tags 104a and 104c in contact with surface 304. Alternatively, where surface 304 is covered with an electrically conductive material, the electrical voltage may be applied directly to surface 304. Step 1706 may be performed in some embodiments.

In step 1708, a first RFID communication signal is transmitted from a first antenna mounted in a first cavity in the surface to a first tag of the web adjacent to the first cavity. For example, as shown in FIG. 11, a first RFID communication signal 612a is transmitted from antenna 308a in cavity 306a to test tag 104c. Tag 104c transmits a response signal 614a to signal 612a.

In step 1710, a second RFID communication signal is transmitted from a second antenna mounted in a second cavity in the surface to a second tag of the web adjacent to the second cavity. For example, as shown in FIG. 11, a second RFID communication signal 612b is transmitted from antenna 308b in cavity 306b to test tag 104f. Tag 104f transmits a response signal 614b to signal 612b.

In an embodiment, flowchart 1710 may further include the step(s) where response signals 614a and 614b are processed to determine whether tags 100c and 100f passed their respective tests. For example, RFID tag test module 402 may be used to process the response signals.

In step 1712, the web is advanced such that a third tag of the web is positioned adjacent to the first cavity and a fourth tag of the web is positioned adjacent to the second cavity. Step 1712 can be repeated as often as necessary to advance further tags into a test position, with steps 1704, 1706, 1708, and 1710 repeated as often as necessary, to test any number of tags of the web.

### Example Computer System Embodiments

In this document, the terms “computer program medium” and “computer usable medium” are used to generally refer to media such as a removable storage unit, a hard disk installed in hard disk drive, and signals (i.e., electronic, electromagnetic, optical, or other types of signals capable of being received by a communications interface). These computer program products are means for providing software to a computer system. The invention, in an embodiment, is directed to such computer program products.

In an embodiment where aspects of the present invention are implemented using software, the software may be stored in a computer program product and loaded into a computer system using a removable storage drive, hard drive, or communications interface. The control logic (software), when executed by a processor, causes the processor to perform the functions of the invention as described herein.

According to an example embodiment, a reader may execute computer-readable instructions to initiate generation of communications signals to communicate with a tag, to process tag responses, to advance a web of tags, etc.

### Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A system for testing radio frequency identification (RFID) tags, comprising:
a body having a surface, wherein the surface has a first cavity and a second cavity formed therein;
a first antenna mounted in the first cavity; and
a second antenna mounted in the second cavity;
wherein the surface is configured to receive a web of RFID tags such that a first tag of the web of RFID tags is positioned adjacent to the first cavity, a second tag of the web of RFID tags is positioned adjacent to the second cavity, and at least one other tag of the web of RFID tags is in contact with the surface to couple an antenna of the at least one other tag to an electrical voltage;
wherein the first antenna is configured to transmit a first RFID communication signal to the first tag and to receive a first response signal from the first tag; and
wherein the second antenna is configured to transmit a second RFID communication signal to the second tag and to receive a second response signal from the second tag.

2. The system of claim 1, wherein tags in the web of RFID tags are arranged in an array of rows and columns, wherein the rows extend along a length of the web in parallel and the columns extend across a width of the web in parallel; and
wherein the first cavity is positioned in the surface of the body such that the first tag is located in a first row and first column of the web and the second cavity is positioned in the surface of the body such that the second tag is located in a second row and second column of the web, wherein the first row is different from the second row, and the first column is different from the second column.

3. The system of claim 2, wherein the surface of the body includes a third cavity, wherein a third tag of the web of RFID tags is positioned adjacent to the third cavity, wherein the third cavity is positioned in the surface of the body such that the third tag is located in a third row and the first column of the web, wherein the third row is different from the first and second rows, and wherein the second row is between the first row and second row, the system further comprising:
a third antenna mounted in the third cavity;
wherein the third antenna is configured to transmit a third RFID communication signal to the third tag and to receive a third response signal from the third tag.

4. The system of claim 3, wherein the surface of the body includes a third cavity, wherein a third tag of the web of RFID tags is positioned adjacent to the third cavity, wherein the third cavity is positioned in the surface of the body such that the third tag is located in the first row and a third column of the web, wherein the third column is different from the first and second columns, and wherein the second column is between the first column and second column, the system further comprising:
a third antenna mounted in the third cavity;
wherein the third antenna is configured to transmit a third RFID communication signal to the third tag and to receive a third response signal from the third tag.

5. The system of claim 3, wherein the surface of the body includes a plurality of cavities arranged in a checkerboard pattern, the plurality of cavities including the first cavity and the second cavity, wherein a corresponding tag of the web of RFID tags is positioned adjacent to each cavity of the plurality of cavities.

6. The system of claim 5, wherein each cavity of the plurality of cavities has a corresponding antenna mounted therein, wherein the antenna mounted in each cavity is configured to transmit a corresponding RFID communication to the corresponding tag.

7. The system of claim 1, wherein the first cavity and the second cavity are both substantially rectangular in shape.

8. The system of claim 7, wherein the first tag is positioned directly diagonally in the array from the second tag.

9. The system of claim 8, wherein a corner of the first cavity nearest to the second cavity is flattened.

10. The system of claim 1, wherein the first cavity has an outer profile in the surface of the body that is greater than or equal to (≧) an outer profile of an antenna of the first tag.

11. The system of claim 1, further comprising a web advancement mechanism configured to advance the web to move a third tag of the web adjacent to the first cavity and a fourth tag of the web adjacent to the second cavity.

12. The system of claim 1, wherein the surface of the body includes at least one opening coupled to a vacuum source, wherein the vacuum source is configured to apply a suction to the web through the at least one opening to hold the web in contact with the surface.

13. The system of claim 1, wherein the first RFID communication signal has a first bandwidth that is non-overlapping with a second bandwidth of the second RFID communication signal.

14. The system of claim 1, further comprising:
a first transmitter coupled to the first antenna and configured to generate the first RFID communication signal; and
a second transmitter coupled to the second antenna and configured to generate the second RFID communication signal;
wherein the first and second transmitters are configured to generate the first second RFID communication signal to be overlapping in time.

15. The system of claim 1, wherein the body comprises a metal plate having opposing first and second surfaces, wherein the surface of the body is the first surface of the metal plate.

16. The system of claim 15, wherein the metal plate includes at least one opening that is open at the first surface and the second surface, the system further comprising:
at least one hose coupled to said at least one opening; and
a vacuum source coupled said at least one hose, wherein the vacuum source is configured to apply a suction to the web through the at least one hose to the at least one opening to hold the web in contact with the first surface of the metal plate.

17. The system of claim 1, wherein the electrical voltage is an electrical ground.

18. The system of claim 1, wherein the at least one other tag of the web in contact with the surface includes a first plurality of tags adjacent to the first tag in the web and a second plurality of tags adjacent to the second tag in the web.

19. The system of claim 1, further comprising a tag test module configured to receive and analyze the first response signal to determine whether the first tag passed a first test, and to receive and analyze the second response signal to determine whether the second tag passed a second test.

20. A method for testing radio frequency identification (RFID) tags, comprising:
receiving a web of RFID tags on a surface such that a first tag of the web of RFID tags is positioned adjacent to a first cavity in the surface, a second tag of the web of RFID tags is positioned adjacent to a second cavity in the surface;
transmitting a first RFID communication signal from a first antenna mounted in the first cavity, wherein the first RFID communication signal is configured to test the first tag; and
transmitting a second RFID communication signal from a second antenna mounted in the second cavity, wherein the second RFID communication signal is configured to test the second tag.

21. The method of claim 20, wherein said receiving step comprising:
receiving the web of RFID tags such that at least one tag of the web other than the first and second tags is in contact with the surface to couple an antenna of the at least one tag to an electrical voltage.

22. The method of claim 20, further comprising:
receiving a first response signal from the first tag;
analyzing the first response signal to determine whether the first tag passed a first test;
receiving a second response signal from the second tag; and
analyzing the second response signal to determine whether the second tag passed a second test.

23. The method of claim 20, wherein tags in the web of RFID tags are arranged in an array of rows and columns, wherein the rows extend along a length of the web and the columns extend across a width of the web, wherein said transmitting the first RFID communication signal step comprises:
transmitting the first RFID communication signal from the first antenna mounted in the first cavity positioned in the surface such that the first tag is located in a first row and first column of the web; and
wherein said transmitting the second RFID communication signal step comprises:
transmitting the second RFID communication signal from the second antenna mounted in the second cavity positioned in the surface such that the second tag is located in a second row and second column of the web, wherein the first row is different from the second row, and the first column is different from the second column.

24. The method of claim 23, wherein the surface includes a third cavity, wherein a third tag of the web of RFID tags is positioned adjacent to the third cavity, wherein the third cavity is positioned in the surface such that the third tag is located in a third row and the first column of the web, wherein the third row is different from the first and second rows, and wherein the second row is between the first row and second row, the method further comprising:
transmitting a third RFID communication signal from a third antenna mounted in the third cavity to the third tag, wherein the third RFID communication signal is configured to test the third tag.

25. The method of claim 23, wherein the surface includes a third cavity, wherein a third tag of the web of RFID tags is positioned adjacent to the third cavity, wherein the third cavity is positioned in the surface such that the third tag is located in the first row and a third column of the web, wherein the third column is different from the first and second columns, and wherein the second column is between the first column and second column, the method further comprising:
transmitting a third RFID communication signal from a third antenna mounted in the third cavity to the third tag, wherein the first RFID communication signal is configured to test the first tag.

26. The method of claim 23, wherein the surface includes a plurality of cavities arranged in a checkerboard pattern, the plurality of cavities including the first cavity and the second cavity, wherein a corresponding tag of the web of RFID tags is positioned adjacent to each cavity of the plurality of cavities, the method further comprising:
transmitting RFID communication signals from antennas located in the plurality of cavities, wherein the RFID communications signals are configured to tags of the web of RFID tags positioned adjacent to each cavity.

27. The method of claim 20, further comprising:
advancing the web such that a third tag of the web is positioned adjacent to the first cavity and a fourth tag of the web is positioned adjacent to the second cavity.

28. The method of claim 27, further comprising:
transmitting a third RFID communication signal from the first antenna mounted in the first cavity, wherein the third RFID communication signal is configured to test the third tag; and
transmitting a fourth RFID communication signal from a fourth antenna mounted in the fourth cavity, wherein the fourth RFID communication signal is configured to test the fourth tag.

29. The method of claim 20, further comprising:
applying suction to the web through at least one opening in the surface to hold the web in contact with the surface.

30. The method of claim 20, further comprising:
generating the first RFID communication signal to have a first bandwidth that is non-overlapping with a second bandwidth of the second RFID communication signal.

31. The method of claim 20, further comprising:
transmitting the first RFID communication signal and second RFID communication signal simultaneously.

32. A system for testing radio frequency identification (RFID) tags, comprising:
means for receiving a web of RFID tags on a surface such that a first tag of the web of RFID tags is positioned adjacent to a first cavity in the surface, a second tag of the web of RFID tags is positioned adjacent to a second cavity in the surface;
means for transmitting a first RFID communication signal from a first antenna mounted in the first cavity, wherein the first RFID communication signal is configured to test the first tag; and
means for transmitting a second RFID communication signal from a second antenna mounted in the second cavity, wherein the second RFID communication signal is configured to test the second tag.

33. The system of claim 32, further comprising:
means for grounding an antenna of at least one tag of the web in contact with the surface.

34. The system of claim 32, further comprising:
means for receiving a first response signal from the first tag;
means for analyzing the first response signal to determine whether the first tag passed a first test;
means for receiving a second response signal from the second tag; and
means for analyzing the second response signal to determine whether the second tag passed a second test.

35. The system of claim 32, wherein the surface includes a plurality of cavities arranged in a checkerboard pattern, the plurality of cavities including the first cavity and the second cavity, wherein a corresponding tag of the web of RFID tags is positioned adjacent to each cavity of the plurality of cavities, the method further comprising:
means for transmitting RFID communication signals from antennas located in the plurality of cavities, wherein the RFID communications signals are configured to tags of the web of RFID tags positioned adjacent to each cavity.

36. The system of claim 32, further comprising:
means for advancing the web such that a third tag of the web is positioned adjacent to the first cavity and a fourth tag of the web is positioned adjacent to the second cavity.
